(19) United States
(12) Patent Application Publication
(10) Pub. No.: US 2007/0262723 A1
(43) Pub. Date: Nov. 15, 2007

(54) Plasma Processing Apparatus Control Method for Plasma Processing Apparatus and Evaluation Method for Plasma Processing Apparatus

(76) Inventor: Sumifusa Ikenouchi, Ehime (JP)

Correspondence Address: WENDEROTH, LIND & PONACK, L.L.P., 2033 K STREET N. W., SUITE 800, WASHINGTON, DC, 20006-1021, US

(21) Appl. No.: 10/574,985

(22) PCT Filed: Oct. 24, 2004
(86) PCT No.: PCT/JP04/16179

§ 371 Date: Mar. 19, 2007

(30) Foreign Application Priority Data
Oct. 29, 2003 (JP) 2003-369333
Jul. 14, 2004 (JP) 2004-207332

(51) Int. Cl. H05H 1/00; G01R 27/00

(52) U.S. Cl. 315/111.21; 324/600

(57) ABSTRACT

A plasma processing apparatus comprises: an RF generator operable to output RF power; an impedance matching network operable to receive the RF power; a plasma chamber operable to receive an output from the impedance matching network; a storing unit operable to store information relating to an S parameter of the impedance matching network; and a control unit operable to control an operating condition for the plasma chamber, based on the information relating to the S parameter.

### TECHNICAL FIELD

The present invention relates to a plasma processing apparatusin which power is supplied from a radio frequency (RF) generator to a plasma chamber through an impedance matching network that various kinds of plasma processing are performed in the plasma chamber. The present invention also relates to a control method and an evaluation method for such a plasma processing apparatus.

### BACKGROUND ART

In recent years, plasma processing is widely utilized for surface processing, such as fine processing using dry etching and thin-film formation. In particular, plasma processing has become an indispensable step in manufacturing semiconductor products.

A plasma processing apparatus includes an impedance matching network in order to achieve efficient transmission of RF power from an RF generator to a load resistor in a plasma chamber. The impedance matching network matches an equivalent output impedance of the RF generator (50Ω) to an impedance of the plasma chamber.

This impedance match needs to be maintained to ensure a stable power supply. Therefore, impedance matching needs to be performed in accordance with a change in load of the plasma chamber. For this correction, generally, a capacitor, a coil and the like included in the impedance matching network are controlled variably.

The capacitor, the coil and the like are controlled variably using, for example, a technique disclosed in Japanese patent application publication No. 2001-16779. According to this technique, an impedance measuring device is provided between an impedance matching network and a plasma load. A control unit accurately calculates a change that needs to be made to a capacitance of a variable capacitor, based on an impedance of the plasma load measured by the impedance measuring device and a current capacitance of the variable capacitor. The control unit controls the capacity of the variable capacitor in accordance with a result of the calculation.

In addition, Japanese patent application publication No. H11-121440 discloses the following technique. A monitor is provided between an impedance matching network and a plasma load. The monitor detects an electronic physical quantity. The detected quantity is compared with a predetermined value, to evaluate generation of a plasma.

Furthermore, Japanese patent application publication No. 2003-282542 discloses the following technique. An RF current, measuring device is provided between an impedance matching network and a plasma load. The measuring device measures a leak current before generation of a plasma starts. The measured leak current is compared with a threshold value to control the impedance matching network.

According to these techniques, a control device of a plasma processing apparatus requires an impedance measuring device, a monitor, or an RF current measuring device to be provided between an impedance matching network and a plasma chamber. However, such measuring devices and a monitor require a converter for converting an RF analog signal into a digital signal, and are therefore expensive.

In addition, if any of such measuring devices and a monitor is provided between impedance matching network and a plasma chamber, impedance mismatch occurs between the impedance matching network and the plasma chamber. This causes various changes, and therefore makes it difficult to set operating conditions for the plasma chamber.

### DISCLOSURE OF THE INVENTION

An object of the present invention is to provide a plasma processing apparatus which does not require an impedance measuring device, a monitor or an RF current measuring device and enables a user to set an operating condition for a plasma chamber with ease. The object includes provision of an evaluation method and a control method for the plasma processing apparatus.

The object can be achieved by a plasma processing apparatus including: an RF generator operable to output RF power; an impedance matching network operable to receive the RF power; a plasma chamber operable to receive an output from the impedance matching network; a storing unit operable to store information relating to an S parameter of the impedance matching network; and a control unit operable to control an operating condition for the plasma chamber, based on the information relating to the S parameter.

Here, the information relating to the S parameter of the impedance matching network is at least one of the S parameter of the impedance matching network and a power transmission efficiency of the impedance matching network which is calculated based on the S parameter.

Here, the impedance matching network. is an automatic impedance matching network which, when impedance mismatch occurs between the impedance matching network and the plasma chamber, detects the impedance mismatch, and adjusts a variable capacitor included in the impedance matching network, to achieve impedance match between the impedance matching network and the plasma chamber.

Here, the S parameter of the impedance matching network is measured using an RF network analyzer.

The object can be also achieved by a control method for a plasma processing apparatus in which RF power is supplied by an RF generator to a plasma chamber through an impedance matching network so that plasma processing is performed in the plasma chamber. Here, a power transmission efficiency from the RF generator to the plasma chamber is calculated based on an S parameter of the impedance matching network, and a control unit of the plasma processing apparatus controls the plasma chamber in reference to the power transmission efficiency.

Here, the S parameter of the impedance matching network is S21 which is a forward transmission parameter.

Here, the RF power supplied by the RF generator is controlled in reference to the power transmission efficiency.

The above object can be also achieved by an evaluation method for a plasma processing apparatus in which RF power is supplied by an RF generator to a plasma chamber through an impedance matching network so that plasma processing is performed in the plasma chamber. Here, an RF network analyzer is used to measure an S parameter of the impedance matching network, and a power transmission efficiency from the RF generator to the plasma chamber is calculated based on the measured S parameter.

Here, the S parameter of the impedance matching network is S21 which is a forward transmission parameter.

Here, an amount of power the plasma chamber receives is obtained based on the power transmission efficiency.

Here, when η, RL and Rm respectively denote the power transmission efficiency, a real resistance in the plasma chamber, and a real resistance in the impedance matching network, Rm=(RL/η)−RL.

The above object can be also achieved by an evaluation method for a plasma processing apparatus in which RF power is supplied by an RF generator to a plasma chamber through an impedance matching network so that plasma processing is performed in the plasma chamber. Here, an RF network analyzer is used to measure an S parameter of the impedance matching network, and a matching impedance is obtained using a matching network function of the RF network analyzer.

The above object can be also achieved by an evaluation method for an impedance matching network. Here, an S parameter of an impedance matching network is measured, and converted into a power transmission efficiency η of the impedance matching network, and when RL and Rm respectively denote a real resistance in a load and a real resistance in the impedance matching network, Rm=(RL/η)−RL.

Different from a conventional plasma processing apparatus, the above plasma processing apparatus does not require an expensive component such as an impedance measuring device, a monitor, and an RF current measuring device, between the impedance matching network and the plasma chamber. Furthermore, the above plasma processing apparatus does not have problems which are caused if the above-mentioned measuring devices and monitor are provided between the impedance matching network and the plasma chamber. Thus, an operating condition for the plasma chamber can be set with ease. The plasma processing apparatus requires an RF network analyzer in order to measure an S parameter of the impedance matching network. Here, only one RF network analyzer is necessary for one manufacturer of plasma processing apparatuses. Accordingly, the need for an RF network analyzer does not lead to an increase in cost of manufacturing the plasma processing apparatus.

Conventionally, an amount of power supplied to a plasma chamber can be only estimated. According to the above evaluation method for a plasma processing apparatus, however, an exact amount of power applied to a plasma chamber can be known. In addition, an exact value of a real resistance Rm in an impedance matching network can be known. Furthermore, a power transmission efficiency is obtained based on a measured S parameter. Thus, an excellent operation can be performed in a plasma chamber.

### BRIEF DESCRIPTION OF THE DRAWINGS

FIG. 1 is a block diagram illustrating how a plasma processing apparatus relating to an embodiment of the present invention is used, in order to explain a control method and an evaluation method for the plasma processing apparatus.

FIG. 2 is a block diagram illustrating how an S parameter of an impedance matching network is measured.

FIG. 3 is an equivalent circuit diagram illustrating part of the plasma processing apparatus.

FIG. 4 is an equivalent circuit diagram illustrating how the S parameter of the impedance matching network is measured.

FIG. 5 is used to illustrate S parameters of the impedance matching network in the plasma processing apparatus.

FIG. 6 is used to illustrate the impedance matching network.

### BEST MODE FOR CARRYING OUT THE INVENTION

The following describes an embodiment of the present invention, with reference to the attached figures.

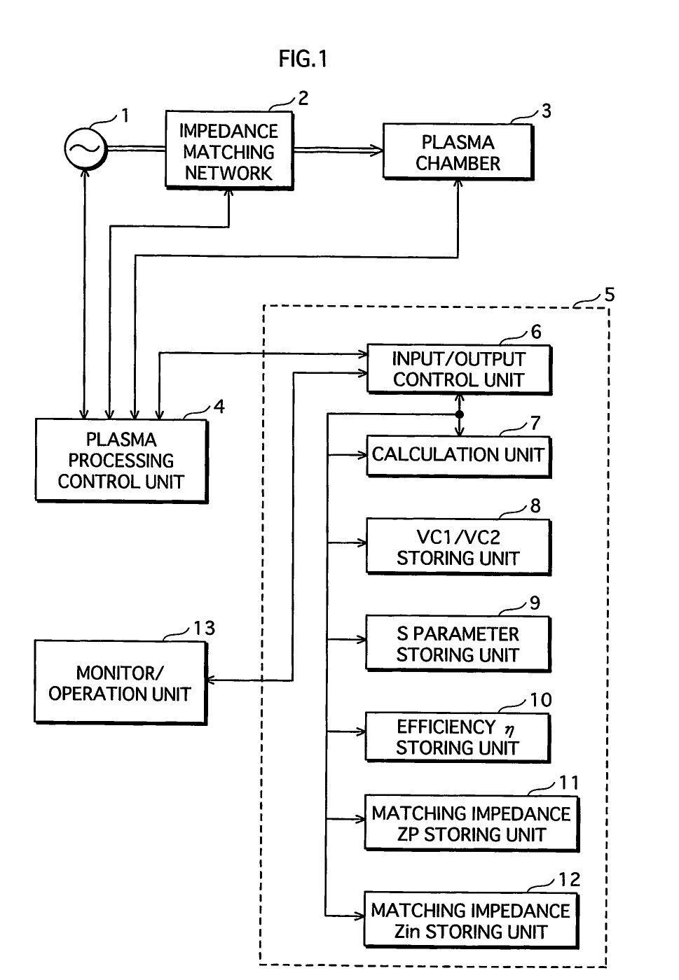

FIG. 1 is a block diagram illustrating a plasma processing apparatus relating to an embodiment of the present invention. As shown in FIG. 1, a radio frequency (RF) generator 1 supplies RFpower (13.56 MHz) to a plasma chamber 3 through an impedance matching network 2. The RF generator 1 and the impedance matching network 2 are connected to each other by a coaxial cable. The impedance matching network 2 and the plasma chamber 3 are directly connected to each other (by means of a coaxial cable in the case of 500 W or lower or a bar such as a copper plate in the case of 500 W or above).

The impedance matching network 2 is an automatic impedance matching network having a general LC circuit. The plasma chamber 3 has a publicly-known construction in which discharge electrodes are arranged with a predetermined interval therebetween. An object to be processed, such as a wafer, is placed between the discharge electrodes, and the object is held in high vacuum when a plasma is generated. Thus, plasma processing can be conducted on a surface of the object.

A plasma processing control unit 4 controls, for example, the RF generator 1, the impedance matching network 2, and operating conditions for the plasma chamber 3 such as a degree of vacuum, a concentration of a gas, and a temperature. Basic components of the plasma processing control unit 4 are commercially available. A calculation/storing unit 5 is constituted by an input/output control unit 6, a calculation unit 7, a VC1/VC2 storing unit 8, an S parameter storing unit 9, an efficiency η storing unit 10, a matching impedance ZP storing unit 11, and a matching impedance Zin storing unit 12. The plasma processing control unit 4 is different from a similar commercially-available product in that the plasma processing control unit 4 can exchange a signal with the input/output control unit 6 included in the calculation/storing unit 5.

Also, a monitor/operation unit 13 is connected to the input/output control unit 6, to exchange a signal with the input/output control unit 6. The monitor/operation unit 13 can be realized using a personal computer.

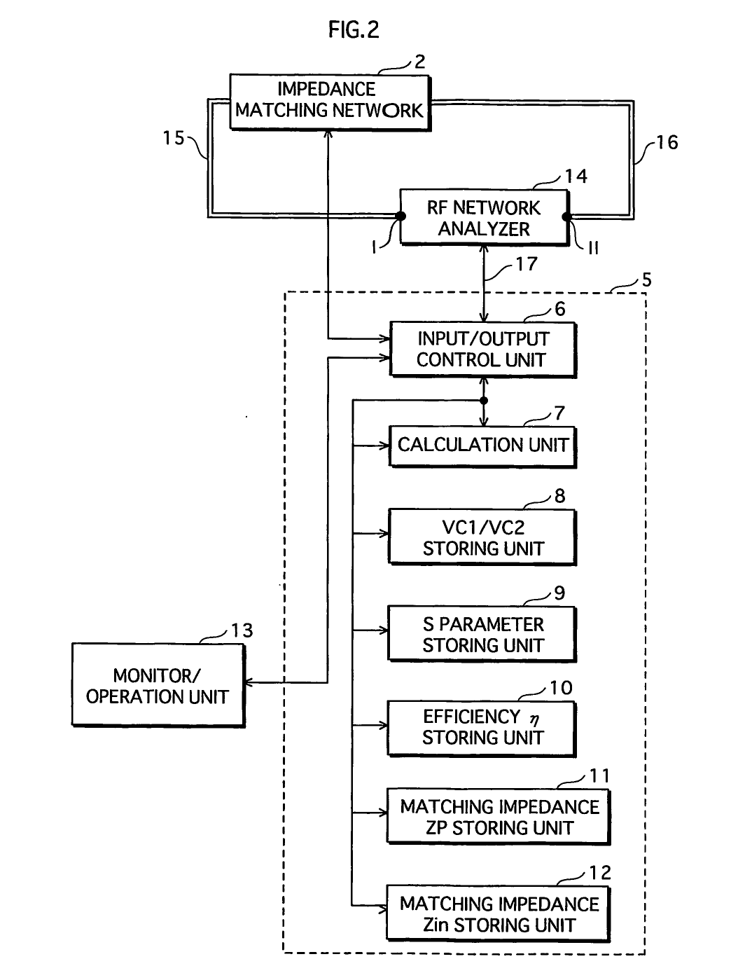

FIG. 2 illustrates how to measure data relating to the impedance matching network 2. A port I of an RF network analyzer 14 is connected to an input terminal of the impedance matching network 2 by means of a mounting coaxial cable 15 (having an equal length to the coaxial cable connecting the RF generator 1 and the impedance matching network 2). A port II of the RF network analyzer 14 is connected to an output terminal of the impedance matching network 2 by means of a measuring coaxial cable 16. Here, an end of the coaxial cable 16 which is connected to the impedance matching network 2 is virtually the port II of the RF network analyzer 14. This is realized by subjecting the port II of the RF network analyzer 14 to error correction after the coaxial cable 16 is connected to the port II of the RF network analyzer 14. Here, the RF network analyzer 14 has a function of conducting the error correction, which is a publicly-known technique. A data output terminal of the RF network analyzer 14 is connected to the input/output control unit 6 of the calculation/storing unit 5 by means of a signal cable 17 for measuring, to exchange a signal with the input/output control unit 6.

The RF network analyzer 14 can be formed by a typical RF network analyzer available in the market. The RF network analyzer 14 can measure reflection performance and transmission performance of an electrical network of an electronic component, based on amplitudes and phases of an input signal and an output signal of the electronic component. For example, the RF network analyzer 14 measures transmission performance of a filter or an attenuator. The RF network analyzer 14 has a function of a matching network at the port II.

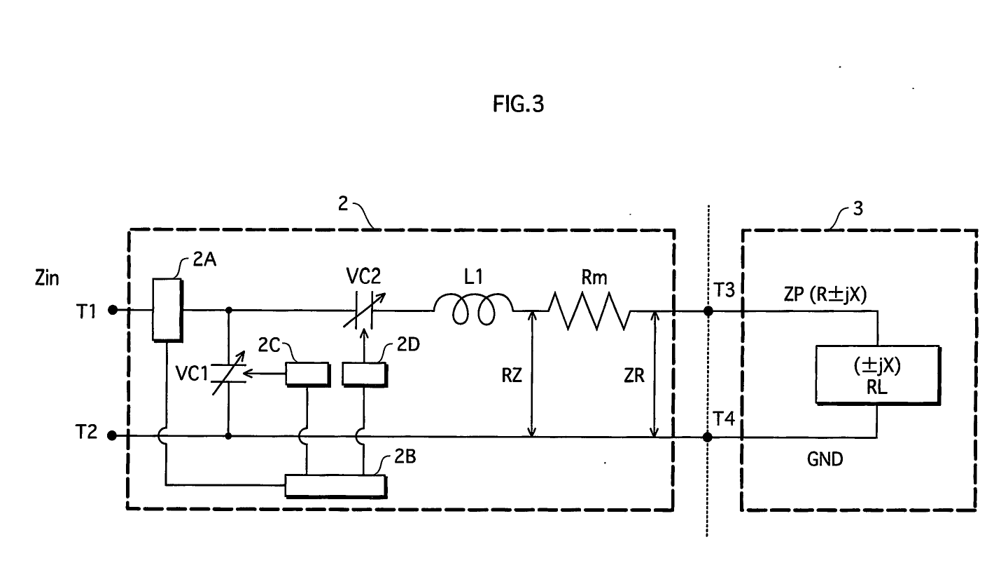

FIG. 3 is an equivalent circuit diagram illustrating the impedance matching network 2 and the plasma chamber 3 (shown in FIG. 1) which are conjugatelymatched. The impedance matching network 2 includes variable capacitors VC1 and VC2, a coil L1, and a real resistance Rm (a total of all resistances in the impedance matching network 2). Input terminals T1 and T2 are connected to the RF generator 1. In FIG. 3, Zin indicates a matching impedance at an input side (the input terminals T1 and T2) of the impedance matching network 2, and ZR indicates a matching impedance at an output side (output terminals T3 and T4).

In FIG. 3, ZP (R±jX) indicates a matching impedance of the plasma chamber 3, and RL indicates a real resistance. When an impedance looking into the RF generator 1 from the input terminals T1 and T2 is 50Ω, and an impedance looking into the impedance matching network 2 from the input terminals T1 and T2 is 50Ω, impedance match is achieved at the input terminals T1 and T2. An impedance ZR looking into the impedance matching network 2 from the output terminals T3 and T4 can be calculated as follows. The above-mentioned impedances of 50Ω are converted into 1.3Ω by means of the capacitors VC1 and VC2. Here, the real resistance Rm of the impedance matching network 2 can be obtained by calculation (mentioned in detail later), and is 0.3Ω. As a result, the impedance ZR=RZ−Rm=1.3Ω-0.3Ω=1Ω.

If an impedance looking into the plasma chamber 3 from the output terminals T3 and T4 (a resistance RL) is 1Ω, the impedance matching network 2 is matched in impedance to the plasma chamber 3. In this case, an imaginary unit of the impedance ZR and that of the impedance ZP do not have to be considered. This situation is called a conjugate match.

If this impedance match (50Ω-50Ω-1Ω-1Ω) is lost, a phase/amplitude detector 2A detects a change in phase and/or amplitude, and a control unit 2B controls motors 2C and 2D. In detail, when a change in phase occurs, the control unit 2B causes the motor 2D to rotate, to adjust the capacitor VC2. When a change in amplitude occurs, the control unit 2B causes the motor 2C to rotate, to adjust the capacitor VC1. In this way, impedance match is again achieved. This is what a commercially-available automatic impedance matching network does.

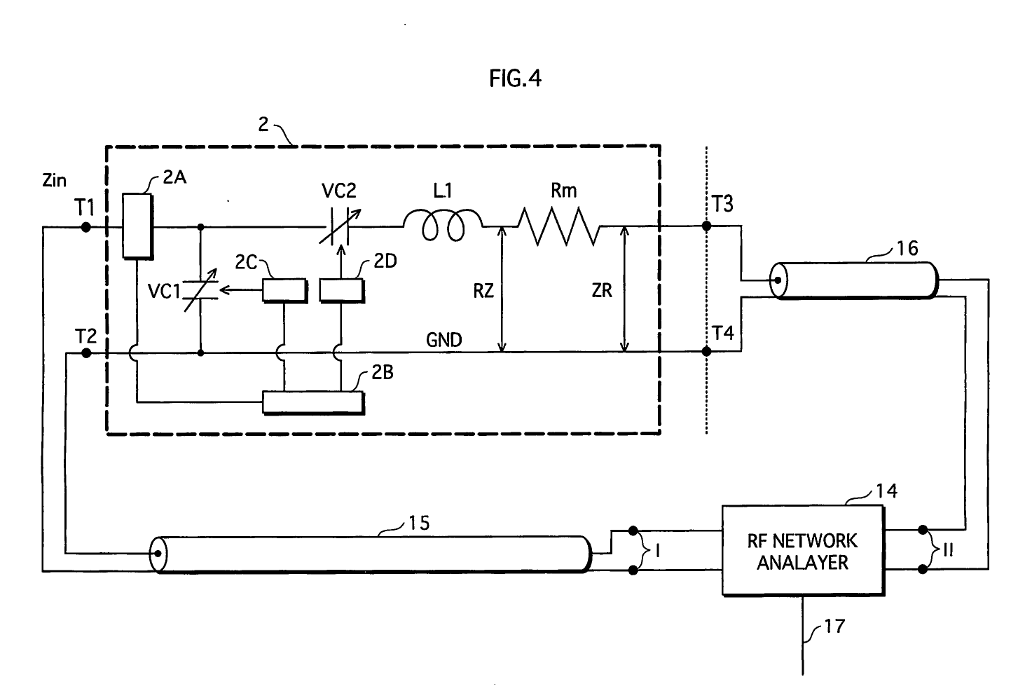

FIG. 4 illustrates how the impedance matching network 2 and the RF network analyzer 14 are connected to each other when the RF network analyzer 14 measures an S parameter of the impedance matching network 2.

The following part describes how an S parameter of the impedance matching network2 is measured. The RF network analyzer 14 measures data relating to the impedance matching network 2 at a manufacturer of the impedance matching network 2. The measured data is stored in the storing units 8 and 9 in the calculation/storing unit 5. The calculation unit 7 performs a calculation based on the data stored in the storing units 8 and 9, to obtain and store a power transmission efficiency η, the matching impedance ZP and the matching impedance Zin in the storing units 10, 11 and 12 respectively.

The impedance matching network 2 and the calculation/storing unit 5 storing data relating to the impedance matching network 2 are combined with other components (the RF generator 1, the plasma chamber 3, the plasma processing control unit 4, and the monitor/operation unit 13) as may be necessary, to be sold.

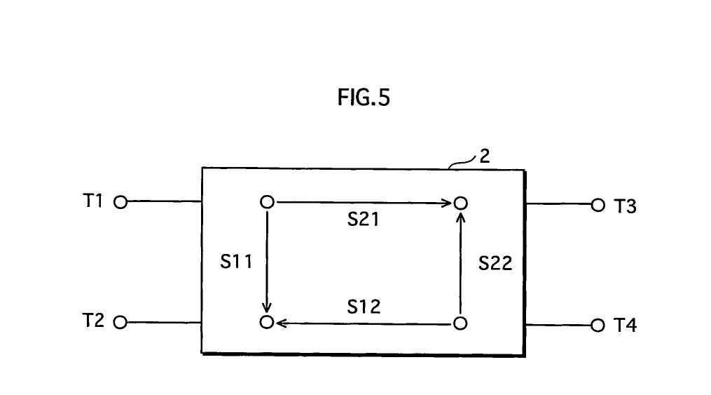

In FIG. 5, an S parameter S11 is a forward reflection coefficient, and observed when a signal is input through the input terminals T1 and T2 into the impedance matching network 2. An S parameter S21 is a forward transmission coefficient, and observed when a signal is input through the input terminals T1 and T2 into the impedance matching network 2. An S parameter S22 is a reverse reflection coefficient, and observed when a signal is input through the output terminals T3 and T4 into the impedance matching network 2. An S parameter S12 is a reverse transmission coefficient, and observed when a signal is input through the output terminals T3 and T4 into the impedance matching network 2.

As shown in FIGS. 2 and 4, a signal having the same frequency (13.56 MHz) as an output from the RF generator 1 is applied from the port I of the RF network analyzer 14 to the input terminals T1 and T2 of the impedance matching network 2.

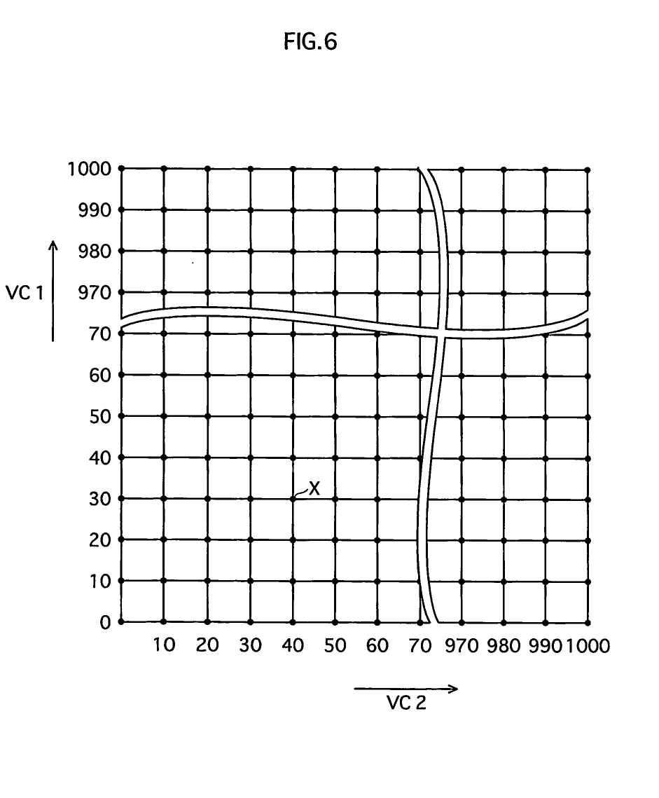

Here, a set of S parameters is measured by changing a voltage of each of the variable capacitor VC1 and the variable capacitor VC2 between 1 and 1000 in increments of one. Which is to say, a set of S parameters is measured for one million different positions each of which is specified by the voltages of the capacitors VC1 and VC2. In FIG. 6, the voltages of the capacitors VC1 and VC2 are set in increments of 10. Instead of being measured for the one million positions, a set of S parameters may be measured by changing the voltages of the capacitors VC1 and VC2 in increments of 10 (that is to say, 10,000 positions). In this case, a set of S parameters for each of the remaining 990,000 positions is obtained by calculation.

Here, for each position specified by the voltages of the capacitors VC1 and VC2, a set of S parameters S11 S21, S12 and S22 is measured and stored. After this, using a function of matching network of the RF network analyzer 14, the circuit is optimized (impedance match is achieved). Thus, physical quantities of the matching impedance ZP and the power transmission efficiency η are obtained and stored.

When a set of S parameters for each of the one million positions is measured, it is first confirmed whether an S parameter S11 is approximately zero (e.g. one ten-thousandth) in any of the one million positions. The output side of the impedance matching network 2 is not actually matched to the RF network analyzer 14. However, an equivalent matching network is connected to the port II of the RF network analyzer 14. Thus, impedance match is achieved both at the input side (50Ω-50Ω) and the output side (1Ω-1Ω) of the impedance matching network 2. As a consequence, an S parameter S11 indicates no reflection. An S parameter S11 is measured for each of the one million positions, and stored in the S parameter storing unit 9.

Here, the impedance of the matching network is equivalent to the matching impedance ZP, and therefore stored in the matching impedance ZP storing unit 11.

After this, an S parameter S21 is measured for each of the one million positions, and stored in the S parameter storing unit 9. A transmission coefficient S21 (measured in decibel) is different for each position due to a variance in a value of the real resistance Rm in the impedance matching network 2. Here, it is assumed that power of 1000 W is supplied from the RF generator 1 to the impedance matching network 2. When a transmission coefficient of three decibels is observed, the power transmission efficiency η is 50%. Therefore, power of 500 W is supplied to the plasma chamber 3. When a transmission coefficient of six decibels is observed, the power transmission efficiency η is 25%. Therefore, power of only 250 W is supplied to the plasma chamber 3.

Subsequently, a signal is output from the port II of the RF network analyzer 14, so that an S parameter S22 is measured for each of the one million positions. Similarly to the measurement of an S parameter S11, it is confirmed whether an S parameter S22 is approximately zero (indicating no reflection) in any of the one million positions. An S parameter S22 is measured for each of the one million positions, and stored in the S parameter storing unit 9.

Lastly, an S parameter S12 is measured for each of the one million positions, and stored in the S parameter storing unit 9. A reverse transmission coefficient S12 is different for each position due to a variance in a value of the real resistance Rm in the impedance matching network 2 and a variance in a value of the load RL.

After this, the calculation unit 7 converts an S parameter S21 into the power transmission efficiency η using a predetermined conversion formula (for converting a value in decibel into an efficiency). The obtained power transmission efficiency η is stored in the efficiency η storing unit 10. The predetermined conversion formula is publicly known and prestored in the calculation unit 7.

Here, the power transmission efficiency η is expressed as follows: η=RL/(Rm+RL). Based on this formula, the real resistance Rm in the impedance matching network 2, which has not been able to be known, can be calculated by a formula:
Rm=(RL/η)−RL.

The following describes how impedance match is maintained while a wafer is processed in the plasma chamber 3.

The plasma processing apparatus shown in FIG. 1 is built by a user. In case of using a new plasma chamber for the plasma chamber 3, it is confirmed whether the new plasma chamber can perform excellent processing having the same quality as an original plasma chamber, through experimenting many plasma chambers of the same kind. The user of the plasma processing apparatus sets operating conditions for the plasma chamber 3.

In detail, a degree of vacuum, a quantity of a gas, a temperature in the plasma chamber 3 and other operating conditions are each set at a predetermined value. Then, a wafer is placed in the plasma chamber 3. When the RF generator 1 is turned on, impedance match is not achieved in the plasma processing apparatus. Accordingly, the plasma chamber 3 is not supplied with a sufficient amount of power, and a plasma is slightly generated in the plasma chamber 3. The impedance matching network 2 then starts to operate, and achieves impedance match in one or two seconds. Thus, the plasma chamber 3 is supplied with a sufficient amount of power, and becomes stable.

Here, it is assumed that an operation in the plasma chamber 3 is defined by an amount of power supplied by the RF generator 1 and a time period required for completing the operation. For example, it takes three minutes to perform an operation A when power of 1000 W (the plasma chamber 3 is estimated to receive a power supply of approximately 700 W) is supplied by the RF generator 1. It takes one minute to perform an operation B when power of 1000 W (the plasma chamber 3 is estimated to receive a power supply of approximately 700 W) is supplied by the RF generator 1. It should be noted that an amount of power supplied to the plasma chamber 3 is only estimated approximately 700 W here, and needs to be actually measured to know an accurate amount of the supplied power. To set operating conditions for the plasma chamber 3, power of 1000 W is, for example, supplied by the RF generator 1, and the voltages of the variable capacitors VC1 and VC2 in the impedance matching network 2 are appropriately set so that a desired amount of power is supplied to the plasma chamber 3. Here, it is assumed that η=700/1000=0.70 and RL=1.0. Since Rm=(RL/η)−RL, Rm=(1.0/0.7)−1.0=0.42857Ω.

While a wafer is being processed in the plasma chamber 3, the state in the plasma chamber 3 varies because of, for example, polishing of the wafer. Specifically speaking, a matching impedance of the plasma chamber 3 (RL) maybe originally 1Ω, but may change to, for example, 1.1Ω. This change causes impedance mismatch to occur, and causes the impedance matching network 2 to start to operate. As a result, the impedance looking into the impedance matching network 2 from the output terminals T3 and T4 is changed to 1.1Ω, thereby achieving impedance match.

Here, because Rm=0.42857Ω and RL=1.1Ω now, the power transmission efficiency η of 0.70 has changed to an efficiency η′=1.1/(0.42857+1.1)=0.71963. Which is to say, the power supply received by the plasma chamber 3 has changed to 719.63 W.

According to this mismatch correction operation, the voltages of the capacitors VC1 and VC2 are varied. As a result, the power transmission efficiency η (η=RL/(Rm+RL)) of the impedance matching network 2 has changed, and the amount of power supplied to the plasma chamber 3 has also changed. It is therefore not certain whether the wafer is properly processed.

To solve this problem, the varied voltages of the capacitors VC1 and VC2 in the impedance matching network 2 are sent to the input/output control unit 6 in the calculation/storing unit 5, through the plasma processing control unit 4. The sent voltages of the capacitors VC1 and VC2, for example, may specify a position X (shown in FIG. 6), according to the VC1/VC2 storing unit 8. Then, a set of S parameters corresponding to the position X is retrieved from the S parameter storing unit 9. Subsequently, a power transmission efficiency ηx corresponding to the position X is retrieved from the efficiency η storing unit 10. After this, the plasma processing control unit 4 appropriately controls the operating conditions for the plasma chamber 3 based on the retrieved power transmission efficiency ηx.

For example, when the power transmission efficiency ηx is 0.71963, the plasma processing control unit 4 may cause the RF generator 1 to output power of 972.72 W (0.70/0.71963×1000). In this way, the plasma chamber 3 receives substantively the same amount of power as is the case of RL=1.0Ω.

The user of the plasma chamber 3 knows, based on his/her experience, which operating condition needs to be adjusted in accordance with the new power transmission efficiency ηx in order to optimize the state in the plasma chamber 3. The user adjusts appropriate one of an amount of power output from the RF generator 1, a degree of vacuum in the plasma chamber 3, a concentration of a gas in the plasma chamber 3, a temperature in the plasma chamber 3 and other operating conditions, through the plasma processing control unit 4.

As shown in FIG. 2, the calculation/storing unit 5 includes the S parameter storing unit 9, the efficiency η storing unit 10, the matching impedance ZP storing unit 11, and the matching impedance Zin storing unit 12. Out of the storing units 9 to 12, however, the calculation/storing unit 5 may only include the S parameter storing unit 9. If such is the case, the calculation unit 7 calculates and outputs a power transmission efficiency η, a matching impedance ZP, and a matching impedance Zin. Alternatively, the calculation/storing unit 5 may only include the efficiency η storing unit 10 so as to store a power transmission efficiency η obtained by the calculation unit 7 based on an S parameter. In other words, the calculation/storing unit 5 may store at least one of an S parameter and a power transmission efficiency η.

### INDUSTRIAL APPLICABILITY

The present invention is especially useful to evaluate and control plasma processing conducted in manufacturing a semiconductor product.

1. A plasma processing apparatus comprising:
an RF generator operable to output RF power;
an impedance matching network operable to receive the RF power;
a plasma chamber operable to receive an output from the impedance matching network;
a storing unit operable to store information relating to an S parameter of the impedance matching network; and
a control unit operable to control an operating condition for the plasma chamber, based on the information relating to the S parameter.

2. The plasma processing apparatus of claim 1, wherein
the information relating to the S parameter of the impedance matching network is at least one of the S parameter of the impedance matching network and a power transmission efficiency of the impedance matching network which is calculated based on the S parameter.

3. The plasma processing apparatus of claim 1, wherein
the impedance matching network is an automatic impedance matching network which, when impedance mismatch occurs between the impedance matching network and the plasma chamber, detects the impedance mismatch, and adjusts a variable capacitor included in the impedance matching network, to achieve impedance match between the impedance matching network and the plasma chamber.

4. The plasma processing apparatus of claim 1, wherein
the S parameter of the impedance matching network is measured using an RF network analyzer.

5. A control method for a plasma processing apparatus in which RF power is supplied by an RF generator to a plasma chamber through an impedance matching network so that plasma processing is performed in the plasma chamber, wherein
a power transmission efficiency from the RF generator to the plasma chamber is calculated based on an S parameter of the impedance matching network, and
a control unit of the plasma processing apparatus controls the plasma chamber in reference to the power transmission efficiency.

6. The control method of claim 5, wherein
the S parameter of the impedance matching network is S21 which is a forward transmission parameter.

7. The control method of claim 5, wherein
the RF power supplied by the RF generator is controlled in reference to the power transmission efficiency.

8. An evaluation method for a plasma processing apparatus in which RF power is supplied by an RF generator to a plasma chamber through an impedance matching network so that plasma processing is performed in the plasma chamber, wherein
an RF network analyzer is used to measure an S parameter of the impedance matching network, and
a power transmission efficiency from the RF generator to the plasma chamber is calculated based on the measured S parameter.

9. The evaluation method of claim 8, wherein
the S parameter of the impedance matching network is S21 which is a forward transmission parameter.

10. The evaluation method of claim 8, wherein
an amount of power the plasma chamber receives is obtained based on the power transmission efficiency.

11. The evaluation method of claim 8, wherein
when η, RL and Rm respectively denote the power transmission efficiency, a real resistance in the plasma chamber, and a real resistance in the impedance matching network, Rm=(RL/η)−RL.

12. An evaluation method for a plasma processing apparatus in which RF power is supplied by an RF generator to a plasma chamber through an impedance matching network so that plasma processing is performed in the plasma chamber, wherein
an RF network analyzer is used to measure an S parameter of the impedance matching network, and
a matching impedance is obtained using a matching network function of the RF network analyzer.

13. An evaluation method for an impedance matching network, wherein
an S parameter of an impedance matching network is measured, and converted into a power transmission efficiency η of the impedance matching network, and
when RL and Rm respectively denote a real resistance in a load and a real resistance in the impedance matching network, Rm=(RL/η)−RL.

14. The control method of claim 6, wherein
the RF power supplied by the RF generator is controlled in reference to the power transmission efficiency.

15. The evaluation method of claim 9, wherein
an amount of power the plasma chamber receives is obtained based on the power transmission efficiency.

16. The evaluation method of claim 9, wherein
when η, RL and Rm respectively denote the power transmission efficiency, a real resistance in the plasma chamber, and a real resistance in the impedance matching network, Rm=(RL/η)−RL.
